(19) United States
(12) Patent Application Publication
(10) Pub. No.: US 2025/0159866 A1
(43) Pub. Date: May 15, 2025

(54) SEMICONDUCTOR STRUCTURE

(71) Applicant: Fujian Jinhua Integrated Circuit Co., Ltd., Quanzhou City (CN)

(72) Inventor: Xinyue He, Quanzhou City (CN)

(73) Assignee: Fujian Jinhua Integrated Circuit Co., Ltd., Quanzhou City (CN)

(21) Appl. No.: 18/673,342

(22) Filed: May 24, 2024

(30) Foreign Application Priority Data
Nov. 13, 2023 (CN) 202311506859.5
Nov. 13, 2023 (CN) 202323064913.3

(51) Int. Cl. H10B 12/00

(52) U.S. Cl. CPC H10B 12/315; H10B 12/0335; H10B 12/09; H10B 12/34; H10B 12/50

(57) ABSTRACT

A semiconductor structure includes a substrate, plug structures and spacers. The substrate includes active areas and a trench isolation. The plug structures and the spacers are alternately arranged on the substrate. The plug structures include a first plug disposed on one of the active areas and a second plug disposed on the trench isolation. The first plug includes a first conductive layer and a second conductive layer from bottom to top. The second plug includes a first insulating layer and a third conductive layer from bottom to top. A bottom surface of the third conductive layer is lower than a bottom surface of the second conductive layer.

### BACKGROUND OF THE INVENTION

### 1. Field of the Invention

The present invention generally relates to a semiconductor structure, and more particularly, to a semiconductor structure including plug structures disposed on trench isolation and active areas, respectively.

### 2. Description of the Prior Art

A dynamic random access memory (DRAM) is a kind of volatile memory, which includes an array region consisting of a plurality of memory cells and a peripheral region consisting of a control circuit. Each memory cell includes a transistor and a capacitor electrically connected to the transistor, and the transistor controls storage or release of charges into or from the capacitor to achieve the purpose of data storage. The control circuit can address each memory cell through word lines (WL) and bit lines (BL), which are distributed all over the array area and are electrically connected to the memory cells, thereby controlling data access to the memory cells.

In order to obtain enhanced chip density, the structure of the memory cells has been developed towards a three-dimensional configuration, e.g., buried word lines and stacked capacitors. According to the technology of stacked capacitors, capacitors of the memory cells are disposed above the substrate and electrically connected to the transistors in the substrate in a vertical direction through plug structures and connection pad structures, thereby saving the substrate area occupied by the capacitors. In addition, it is easy to increase capacitance by increasing height of an electrode plate of the capacitor. However, there are still some technical problems that need to be further solved. For example, it is necessary to ameliorate structural defects caused by stress in the peripheral region.

### SUMMARY OF THE INVENTION

An object of the present invention is to provide semiconductor structure including plug structures disposed on trench isolation and active areas, respectively. Compositions of both the plug structures include conductive layers for regulating stress between the cell region and the peripheral region, thereby ameliorating structural defects caused by stress variation.

An embodiment of the present invention provides a semiconductor structure, which includes a substrate, a plurality of plug structures and a plurality of spacers. The substrate includes active areas and a trench isolation. The plurality of plug structures and the plurality of spacers are alternately arranged on the substrate. The plurality of plug structures include a first plug disposed on one of the active areas and a second plug disposed on the trench isolation. The first plug includes a first conductive layer and a second conductive layer from bottom to top. The second plug includes a first insulating layer and a third conductive layer from bottom to top. A bottom surface of the third conductive layer is lower than a bottom surface of the second conductive layer.

Another embodiment of the present invention provides a semiconductor structure, which includes a substrate, a plurality of plug structures and a plurality of spacers. The substrate includes a cell region and a peripheral region. The cell region includes active areas, and the peripheral region includes a trench isolation. The plurality of plug structures and the plurality of spacers are alternately arranged in the cell region and the peripheral region. The plurality of plug structures include a first plug disposed on one of the active area and a fourth plug disposed on the trench isolation. The first plug includes a first conductive layer and a second conductive layer from bottom to top. The fourth plug comprises a third insulating layer, a sixth conductive layer and a seventh conductive layer from bottom to top. The first conductive layer and the sixth conductive layer include the same semiconductor material, and the second conductive layer and the seventh conductive layer comprise a same metal material.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 to FIG. 7 are schematic cross-sectional views illustrating intermediates of a semiconductor structure according to an embodiment of the present invention in a manufacturing process.

FIG. 8 to FIG. 10 are schematic cross-sectional views illustrating intermediates of a semiconductor structure according to another embodiment of the present invention in a manufacturing process.

FIG. 11 is a schematic cross-sectional view illustrating a semiconductor structure according to an embodiment of the present invention.

FIG. 12 is a schematic cross-sectional view illustrating a semiconductor structure according to another embodiment of the present invention.

### DETAILED DESCRIPTION

For better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

In order to make those of ordinary skilled in the art readily understand the invention and for simplifying the drawings, several drawings in this disclosure only depict a part of the semiconductor structure, and specific elements in the drawings are not drawn to actual scale. In addition, the number and size of each element in the drawings are only for illustration and are not used to limit the scope of the disclosure. It is understood by those of ordinary in the art that the expressions “on”, “above”, “below”, “upper”, “lower”, “over”, “under”, etc. are used for indicating relative positions of the elements, and all the elements can be turned over while still presenting the same structure. Both configurations should belong to the scope disclosed in this specification.

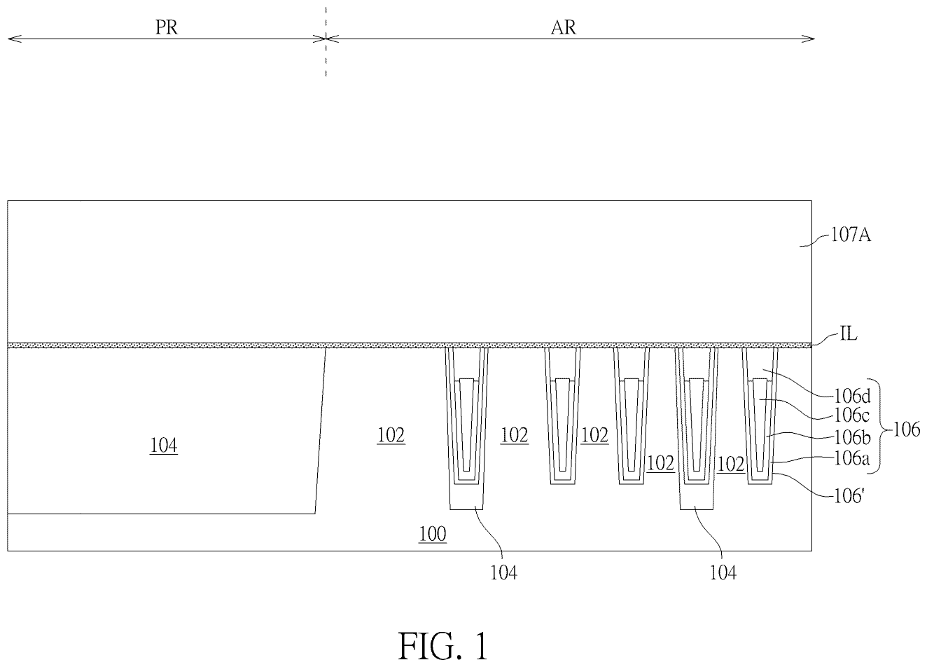

FIG. 1 to FIG. 7 are schematic cross-sectional views illustrating intermediates of a semiconductor structure according to an embodiment of the present invention in a manufacturing process.

The manufacturing process of the semiconductor structure according to the embodiment of the present invention includes the following steps. Please refer to FIG. 1. A substrate 100 is first provided. Then an insulating material layer IL is formed on the substrate 100, and a dielectric layer 107A is firmed on the insulating material layer IL. The substrate 100 may be, for example, but not limited to, a silicon substrate, an epitaxial silicon substrate, a silicon germanium substrate, a silicon carbide substrate or a silicon-on-insulator (SOI) substrate. The substrate 100 includes a cell region AR and a peripheral region PR. The cell region AR may also be referred to as an array region, where memory cells are disposed. The peripheral region PR is contiguous with the cell region AR for dividing the cell region AR from other circuit region of the substrate 100. In some embodiments, the peripheral region PR may also be a region where word lines and bit lines for controlling operations of the memory cells are electrically connected to the peripheral circuit.

As shown in FIG. 1, the substrate 100 may be disposed therein a plurality of isolation structures 104 and a plurality of active areas 102, which are defined in the substrate 100 with the plurality of isolation structures 104. The isolation structures 104 may be, for example, but not limited to, shallow trench isolation (STI) structure.

The substrate 100 may be further disposed therein a plurality of word line structures 106, wherein portions of the plurality of word line structures 106 cutting through the active areas 102 are gate electrodes of the transistors of the memory cell, and portions of the plurality of word line structures 106 cutting through the isolation structures 104 are passing gates. The process of forming the word line structures 106 includes forming word line trenches 106′ cutting through the isolation structures 104 and the active areas 102 in the substrate 100, then forming a gate insulating layer 106a overlying a bottom surface and a sidewall of each of the word line trenches 106′, then forming a work function metal layer 106b and a conductive layer 106c to fill lower parts of the word line trenches, and then an insulating cap layer 106d is formed to fill upper parts of the word line trenches 106′. The insulating cap layer 106d and the gate insulating layer 106a may both include dielectric materials, for example, but not limited to, silicon oxide (SiO₂), silicon nitride (SiN), silicon (SiON), oxynitride silicon nitride (SiCN), nitrogen-doped silicon carbide (NDC) or a combination of the above materials. In some embodiments, the gate insulating layer 106a may include a high-k metal oxide dielectric material, for example, but not limited to, hafnium oxide (HfO), hafnium oxide silicate (HfSiO), hafnium oxynitride silicate (HfSiON), aluminum oxide (AlO), lanthanum oxide (LaO), lanthanum aluminate (LaAlO), tantalum oxide (TaO), zirconium oxide (ZrO), zirconium oxide silicate (ZrSiO), or hafnium zirconate (HfZrO). A material of the work function metal layer 106b may include an n-type work function metal such as titanium aluminide (TiAl), zirconium aluminide (ZrAl), tungsten aluminide (WAl), tantalum aluminide (TaAl), hafnium aluminide (HfAl) or titanium aluminum carbide (TiAlC), or may include a p-type work function metal such as titanium nitride (TiN), tantalum nitride (TaN) or tantalum carbide (TaC), but it is not limited thereto. The conductive layer 106c may include a metal material such as tungsten (W), copper (Cu), aluminum (Al), titanium (Ti), tantalum (Ta), a compound, an alloy and/or a composite layer of the above-mentioned metals, but it is not limited thereto. It should be understood that other circuit elements and structures, e.g., bit lines and interconnect structures, may be further disposed in the substrate 100 or on the substrate 100, but are not shown in the drawings for simplification.

The insulating material layer IL and the dielectric layer 107A include respective dielectric materials. The suitable dielectric materials may be, for example, but not limited to, silicon oxide (SiO₂), silicon nitride (SiN), silicon oxynitride (SiON), silicon nitride (SiCN) or nitrogen-doped silicon carbide (NDC). According to an embodiment of the present invention, the insulating material layer IL is a composite layer of silicon oxide/nitride/oxide (ONO), and the dielectric layer 107A is a silicon oxide (SiO₂) layer.

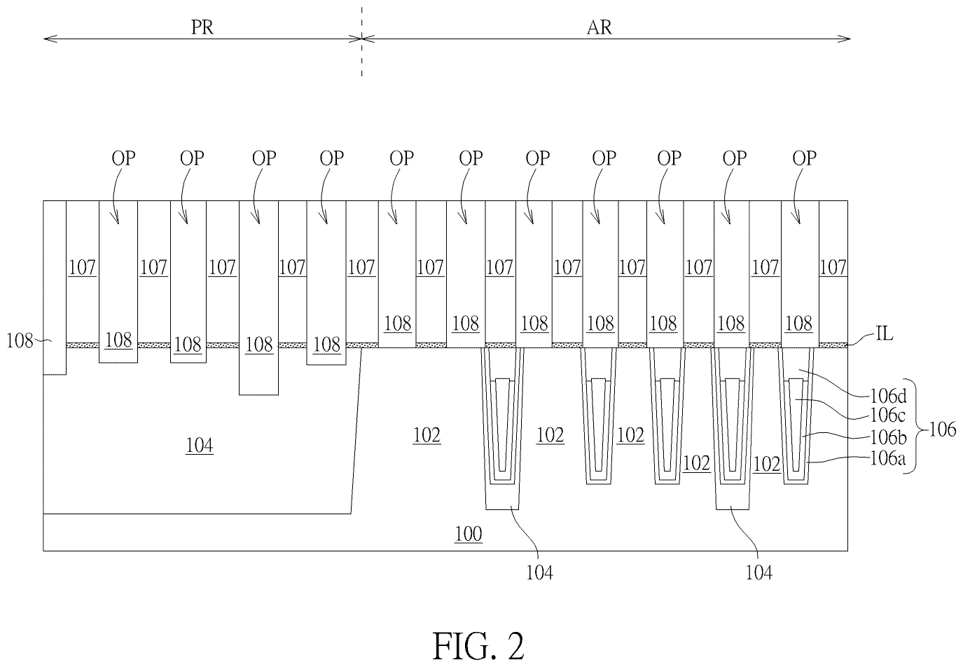

Please refer to FIG. 2. An etching process is then performed on the dielectric layer 107A to form a plurality of openings OP penetrating through the dielectric layer 107A. Subsequently, a deposition process is performed to provide dielectric material (not shown) on the dielectric layer 107A and fill the openings OP. The dielectric material outside the openings OP is removed to obtain spacers 108. Meanwhile, each portion of the dielectric layer 107A between the spacers forms a dielectric plug 107. The spacers 108 are formed of dielectric material different from that forming the dielectric plugs 107, so that the dielectric plugs 107 between the spacers 108 can be selectively removed in a subsequent process. According to an embodiment of the present invention, the dielectric plugs 107 are formed of silicon oxide (SiO₂), and the spacers 108 are formed of silicon nitride (SiN). In some embodiments, bottoms of the openings OP penetrates through the insulating material layer IL, so that bottom surfaces of the spacers 108 are in direct contact with the active areas 102 or the isolation structures 104. In some embodiments, as a region outside the peripheral region, e.g., the region at the left side of FIG. 2 that is outside the peripheral region PR, may be influenced by a loading effect in an etching process, the openings OP in the peripheral region PR as shown may have different depths. In other words, the bottom surfaces of the spacers 108 in the peripheral region PR may not be flush with each other. The dielectric plugs 107 are separated from and is not in direct contact with the active areas 102 and the isolation structures 104 by the insulating material layer IL.

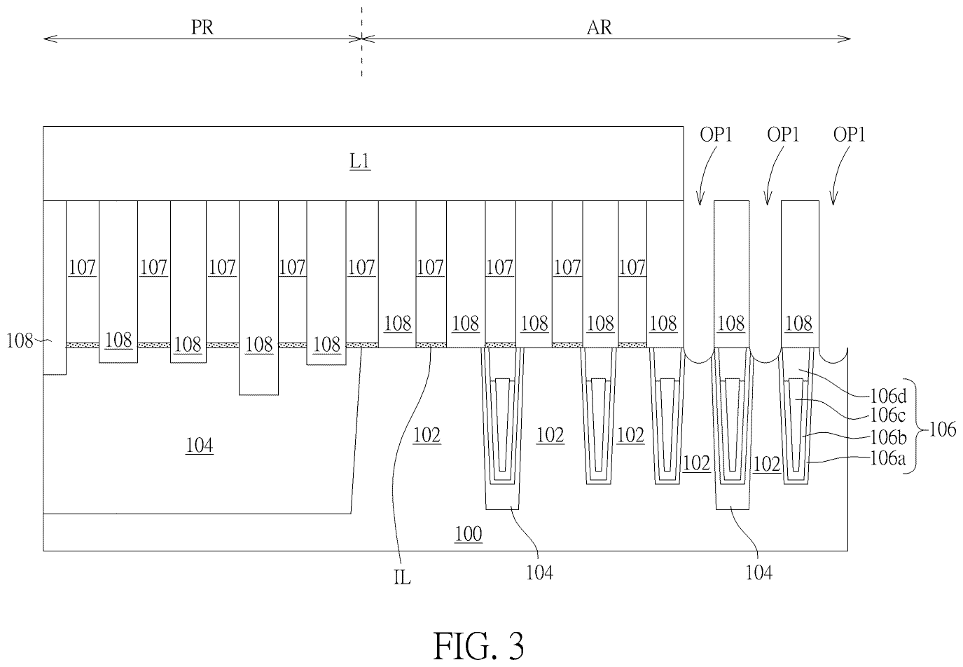

Please refer to FIG. 3. A mask layer L1 is formed to overlie the entire peripheral region PR and expose the dielectric plugs 107 and the spacers 108 in the cell region AR. It is to be noted that the mask layer L1 may further extend toward the cell region AR so as to overlie a portion of the cell region AR next to the peripheral region PR. Subsequently, an etching process, e.g., wet etching, is performed to selectively remove the exposed dielectric plugs 107 and the insulating material layer IL disposed thereunder in the cell region AR, thereby forming a plurality of openings OP1 divided with the spacers 108 and partially exposing the substrate 100. In some embodiments, the substrate 100 exposed from the openings OP1 is a little etched away, and the surface becomes slightly recessed. Thus the bottoms of the openings OP1 are lower than the bottoms of the spacers 108. The mask layer L1 may be, for example, but not limited to, a patterned photoresist layer.

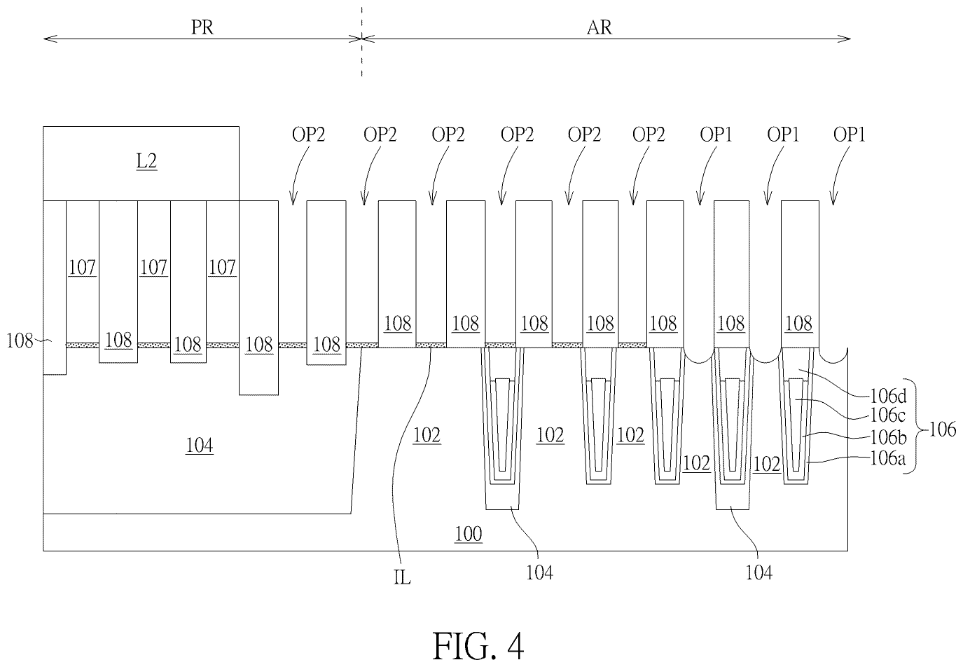

Please refer to FIG. 4. The mask layer L1 is removed, and another mask layer L2 is formed to overlie the peripheral region PR and expose the entire cell region AR. It is to be noted that the mask layer L2 may be pulled back toward the peripheral region PR so as to expose a portion of the peripheral region PR next to the cell region AR. Then an etching process, e.g., wet etching, is performed to selectively remove the exposed dielectric plugs 107, thereby forming a plurality of openings OP2 separated from each other by the spacers 108 in the peripheral region PR and the cell region AR. As shown in FIG. 4, some of the openings OP2 are formed on the active areas 102, while some of the openings OP2 are formed on the isolation structures 104. Furthermore, the insulating material layer IL is exposed from bottoms of the openings OP2, while the active areas 102 or the isolation structures 104 are not exposed.

In an alternative embodiment, the mask layer L1 is not removed after the openings OP1 are formed. Instead, a trimming process is performed to pull back the mask layer L1 toward the peripheral region PR until the mask layer L1 is at a position equivalent to an edge of the mask layer L2 as shown in FIG. 4. Accordingly, the dielectric plugs 107 to be removed subsequently can be exposed and etched to form the openings OP2 with the trimmed mask layer L1.

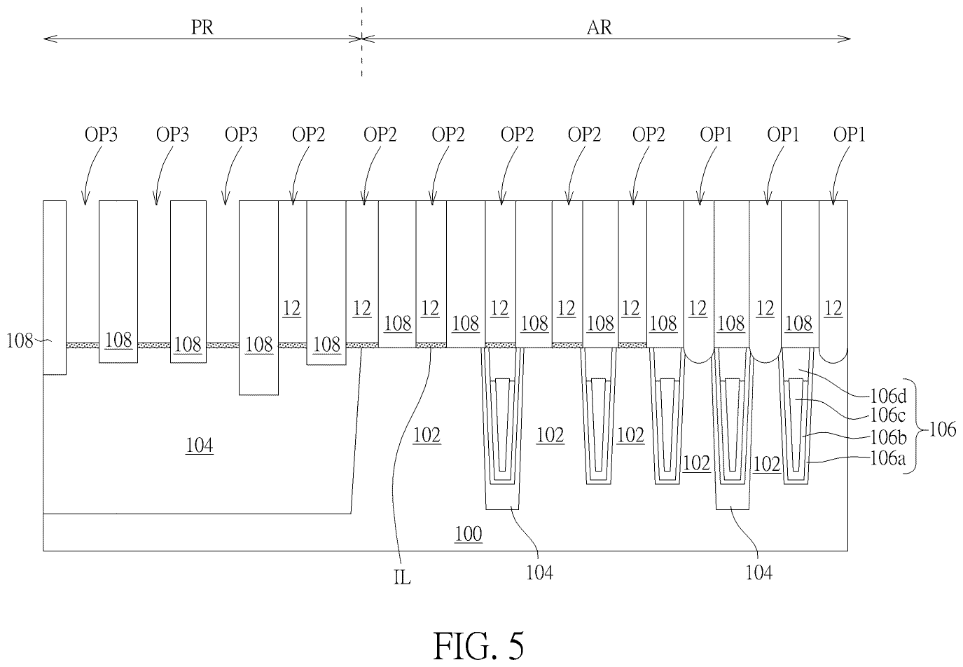

Please refer to FIG. 5. After the remaining mask layer L2 (or the mask layer L1 in the alternative embodiment) is completely removed, a conductive material 12 is formed to overlie the cell region AR and the peripheral region PR and fill the openings OP1 and OP2. Then a chemical mechanical polishing process or an etching process is performed to remove the conductive material 12 outside the openings OP1 and OP2 until top surfaces of the spacers 108 and the remaining dielectric plugs 107 in the peripheral region PR are exposed. The conductive material 12 may include a semiconductor material. Suitable semiconductor material may include, for example, but not limited to, crystalline silicon, polycrystalline silicon, amorphous silicon, doped silicon, silicon germanium (SiGe), and any other suitable semiconductor material. In some embodiments, the conductive material 12 may include polycrystalline silicon. In this embodiment, the conductive material 12 in the openings OP1 is in direct contact with the substrate 100. The conductive material 12 in the openings OP2 is divided from and not in direct contact with the substrate 100 by the insulating material layer IL. Subsequently, an etching process, e.g., wet etching, is performed to selectively remove the remaining dielectric plugs 107 in the peripheral region PR, thereby forming a plurality of openings OP3 in the peripheral region PR, which are divided with the spacers 108. As shown in FIG. 5, the openings OP3 are formed on the isolation structures 104, and the insulating material layer IL is exposed from bottoms of the openings OP3 while the isolation structures 104 are not exposed.

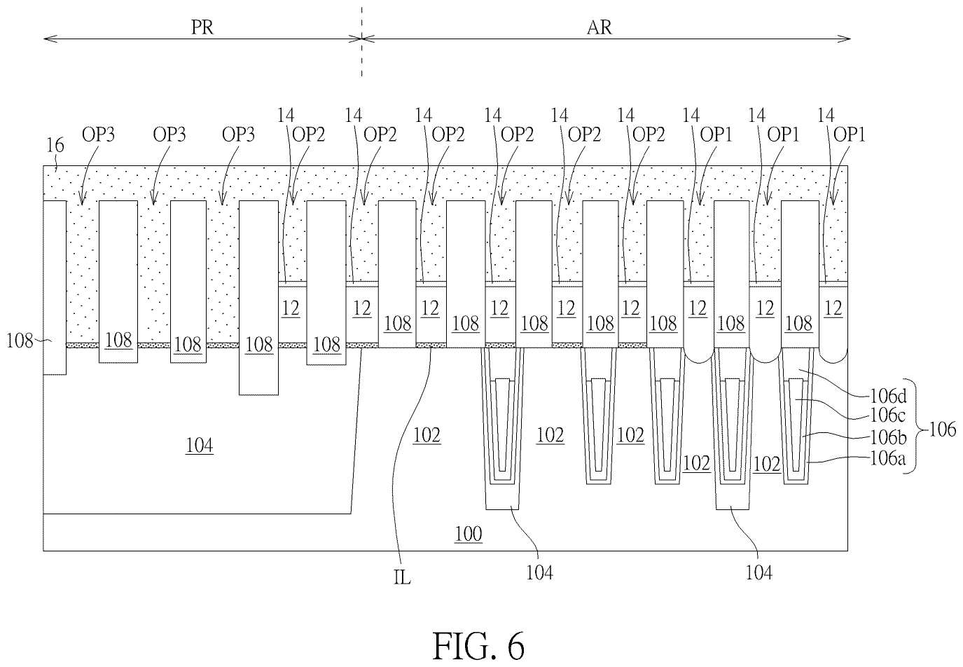

Please refer to FIG. 6. After the openings OP3 are formed, an etching process is performed to remove a part of the conductive material 12 in the openings OP1 and the openings OP2 until the remaining conductive material 12 only exist in respective lower parts of the openings OP1 and the openings OP2 while respective upper parts of the openings OP1 and the openings OP2 are exposed. In some embodiments, the heights of the conductive material 12 remaining in the openings OP1 and the openings OP2 are substantially equal to ½-⅓ the total depths of the openings OP1 and the openings OP2, respectively, but it is not limited thereto. Then another conductive material 16 is formed to overlie the spacers 108 and fill the openings OP1, OP2 and OP3. The conductive material 16 may include a metal material. Suitable metal material may include, for example, but not limited to, metal such as tungsten (W), copper (Cu), aluminum (Al), titanium (Ti), tantalum (Ta), a compound, an alloy and/or a composite layer of the above-mentioned metals. In some embodiments, the conductive material 16 may include tungsten (W). In some embodiments, a metal silicide layer 14 having a single-layer or multi-layer structure formed of, for example, but not limited to, titanium silicide (TiSi), tungsten silicide (WSi), cobalt silicide (CoSi) and/or any other metal silicide material, may be disposed between the conductive material 12 and the conductive material 16.

In an alternative embodiment, the manufacturing processes illustrated in FIG. 5 and FIG. 6 may be adjusted to continue performing the etching process to partially remove the conductive material 12 in the openings OP1 and the openings OP2 until the remaining conductive material 12 is etched to specified levels of depths into the openings OP1 and the openings OP2 after the conductive material 12 outside the openings OP1 and the openings OP2 are removed and the top surfaces of the spacers 108 and the remaining dielectric plugs 107 are exposed. After that, the etching process for selectively removing the dielectric plugs 107 in the peripheral region PR is performed to form the openings OP3.

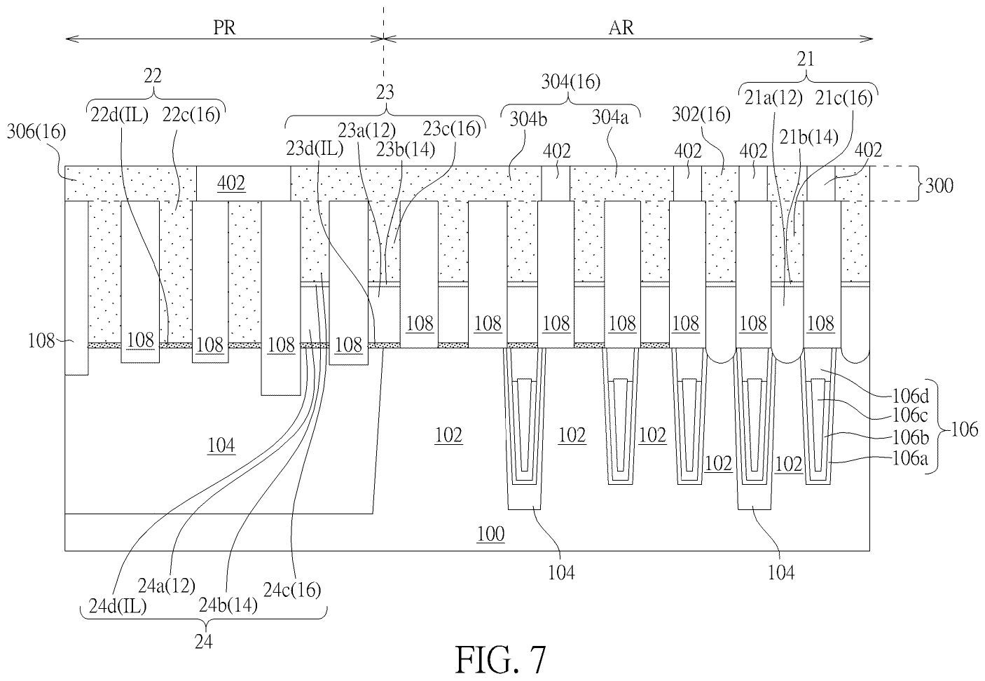

Please refer to FIG. 7. A recessing process, e.g., microlithography and etching process, is performed to remove redundant part of the conductive material 16, and meanwhile, the conductive material 16 is patterned into a plurality of connection pads 302, a dam pad 304 and an extension pad 306, which are isolated from each other. The connection pads 302 are disposed in the cell region AR, the extension pad 306 is disposed in the peripheral region PR, the dam pad 304 is disposed between the connection pads 302 and the extension pad 306 and crosses the cell region AR and the peripheral region PR. In some embodiments, the dam pad 304 may include a first portion 304a and a second portion 304b, which are separate from each other. After completing the recessing process, a deposition process and a planarization process are performed to form a dielectric material 402, which fills recesses among the connection pads 302, the dam pad 304 and the extension pad 306 so as to ensure electric insulation between the structures. Meanwhile, the planarization of surfaces facilitates advancement of subsequent processes. The dielectric material 402 may include, for example, but not limited to, silicon oxide (SiO₂), silicon nitride (SiN), silicon oxynitride (SiON), silicon nitride (SiCN), nitrogen-doped silicon carbide (NDC), low-k dielectric material such as fluorinated silica glass (FSG), silicon carbide oxide (SiCOH), spin-on glass, porous low-k dielectric material, organic polymer dielectric material, or a combination of the above materials. According to an embodiment of the present invention, the dielectric material 402 includes silicon nitride (SiN). The connection pads 302, the dam pad 304, the extension pad 306 and the dielectric material 402 form a connecting layer 300 of the semiconductor structure.

Up to now, a semiconductor structure according to this embodiment of the present invention is completed. As shown in FIG. 7, the semiconductor structure includes a substrate 100. The substrate 100 includes a cell region AR and a peripheral region PR. The cell region AR includes active areas 102. The peripheral region PR includes a trench isolation 104. A plurality of plug structures and a plurality of spacers 108 are alternately arranged in the cell region AR and the peripheral region PR along a specified direction, e.g., an extending direction of a bit line structure. The plurality of plug structures include a plurality of plug structures disposed on the active areas 102, such as the first plug 21, and at least one plug structure disposed on the trench isolation 104, such as the second plug 22 or the fourth plug 24. In some embodiments, the semiconductor structure may include both the second plug 22 and the fourth plug 24. The first plug 21 includes a lower first conductive layer 21a and an upper second conductive layer 21c. The second plug 22 includes a lower first insulating layer 22d and an upper third conductive layer 22c. The fourth plug 24 includes a lower third insulating layer 24d, an intermediate sixth conductive layer 24a and an upper seventh conductive layer 24c.

The first conductive layer 21a is formed of the conductive material 12. In some embodiments, the first conductive layer 21a includes a semiconductor material. The second conductive layer 21c is formed of the conductive material 16. In some embodiments, the second conductive layer 21c includes a metal material. The sixth conductive layer 24a is also formed of the conductive material 12 and may include the same material, e.g., semiconductor material, as the first conductive layer 21a. The third conductive layer 22c and the seventh conductive layer 24c are both formed of the conductive material 16 and may include the same material, e.g., metal material, as the second conductive layer 21c. In some embodiments, the metal material includes tungsten (W).

In some embodiments, a top surface of the third conductive layer 22c is substantially flush with a top surface of the second conductive layer 21c, i.e., also in flush with a bottom surface of the connecting layer 300. Meanwhile, a bottom surface of the third conductive layer 22c is lower than a bottom surface of the second conductive layer 21c.

In some embodiments, the first conductive layer 21a is in direct contact with the active area 102, and the first insulating layer 22d is in direct contact with the trench isolation 104.

In some embodiments, a metal silicide layer 21b is further disposed between the first conductive layer 21a and the second conductive layer 21c. In some embodiments, a metal silicide layer 24b is further disposed between the sixth conductive layer 24a and the seventh conductive layer 24c. The bottom surface of the third conductive layer 22c is lower than a bottom surface of the metal silicide layer 21b.

The first insulating layer 22d is formed of the insulating material layer IL. In some embodiments, the first insulating layer 22d is a composite layer formed of silicon oxide-nitride-oxide (ONO).

In some embodiments, the plurality of plug structures further include at least one plug structure, e.g., third plug 23, crossing a junction between one of the active areas 102 and the trench isolation 104. The third plug 23 includes a lower second insulating layer 23d, an intermediate fourth conductive layer 23a and an upper fifth conductive layer 23c. The fourth conductive layer 23a is also formed of the conductive material 12 and may include the same material, e.g., semiconductor material, as the first conductive layer 21a. The fifth conductive layer 23c is also formed of the conductive material 16 and may include the same material, e.g., metal material, as the second conductive layer 21c. In some embodiments, a metal silicide 23b may further be disposed between the fourth conductive layer 23a and the fifth conductive layer 23c.

In some embodiments, the second insulating layer 23d is also formed of the insulating material layer IL and may include the same material and substantially the same thickness as the first insulating layer 22d. In some embodiments, the second insulating layer 23d is a silicon oxide-nitride-oxide (ONO) composite layer.

In some embodiments, the semiconductor structure further includes a connecting layer 300 disposed on the plug structures and the spacers 108. The connecting layer 300 includes a plurality of connection pads 302 in the cell region AR, at least one extension pad 306 in the peripheral region PR and at least one dam pad 304 crossing the cell region AR and the peripheral region PR. One of the connection pads 302 is disposed on the first plug 21 and integrally formed with the second conductive layer 21c. The extension pad 306 is disposed on the second plug 22 and integrally formed with the third conductive layer 22c. The dam pad 304 is disposed on the third plug 23 and the fourth plug 24 and integrally formed with the fifth conductive layer 23c and the seventh conductive layer 24c.

Hereinafter, different embodiments of the present invention will be described, and in order to simplify the description, the following description will mainly focus on distinctive parts of the embodiments, and the same parts will not be repeated. In addition, the same parts in various embodiments of the present invention are labeled with the same reference numerals to facilitate cross-reference among various embodiments.

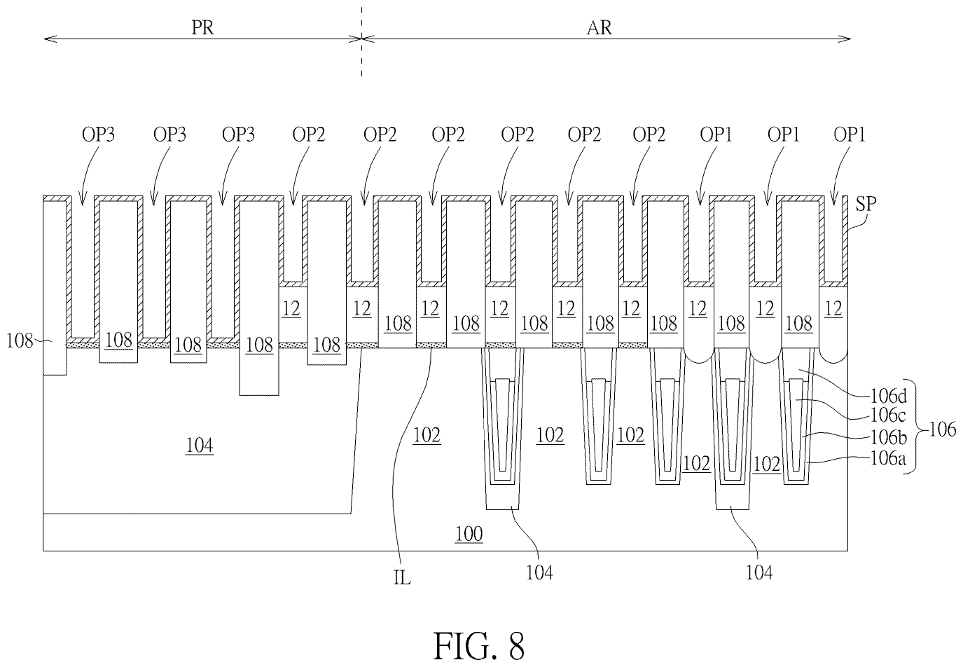

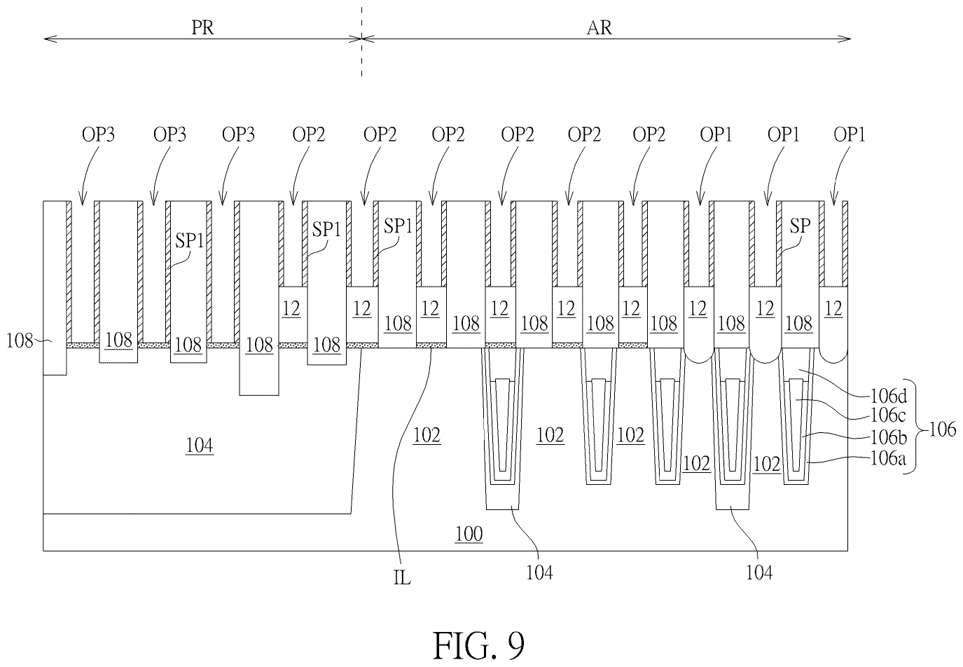

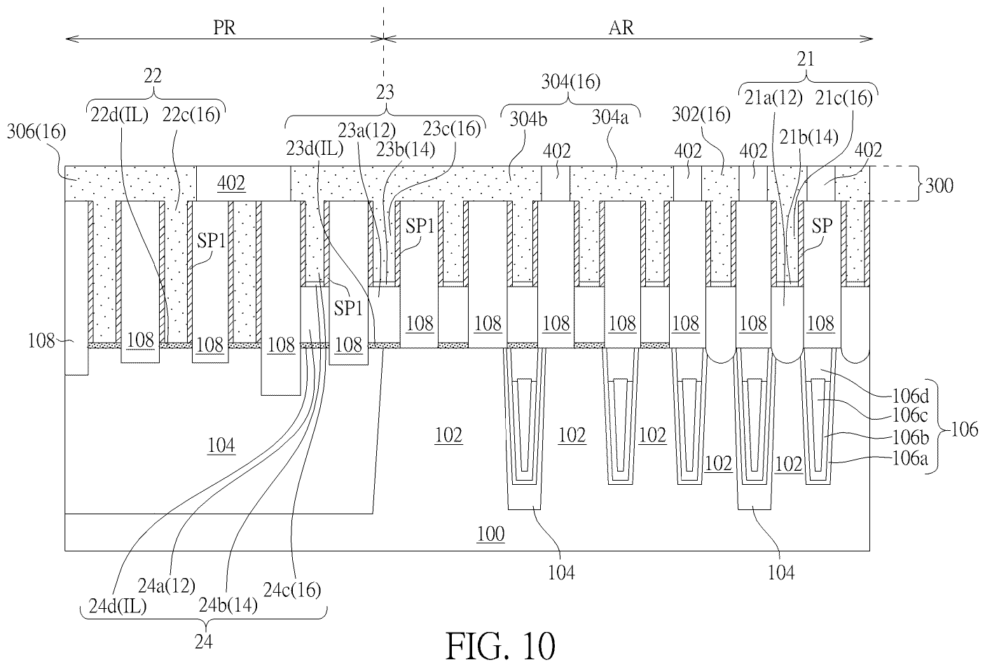

FIG. 8 to FIG. 10 are schematic cross-sectional views illustrating intermediates of a semiconductor structure according to another embodiment of the present invention in a manufacturing process. The semiconductor device in this embodiment mainly differs from the semiconductor device in the embodiment illustrated in FIG. 1 to FIG. 7 in that the semiconductor device in this embodiment further includes s isolation sidewalls SP1 disposed between the conductive material 16 of the plug structures, e.g., the first conductive layer 21c of the first plug 21, and the spacers 108. Please refer to FIG. 8. The method forming the isolation sidewalls SP1 may include, after forming the openings OP3 and etching back the conductive material 12 down to respective lower parts of the openings OP1 and the openings OP2, forming a sidewall material layer SP to conformally overlie sidewalls and bottoms of the openings OP1, openings OP2 and openings OP3 and top surfaces of the spacers 108, wherein at this step the bottoms of the openings OP1 and the openings OP2 are common to the top surface of the conductive material 12. The sidewall material layer SP may include a dielectric material. Suitable dielectric material may include, for example, but not limited to, silicon oxide (SiO₂), silicon nitride (SiN), silicon oxynitride (SiON), silicon nitride (SiCN), nitrogen-doped silicon carbide (NDC), etc. According to an embodiment of the present invention, the sidewall material layer SP includes silicon nitride (SiN). As shown in FIG. 9, a portion of the sidewall material layer SP formed on the top surfaces of the spacers 108 and the bottoms of the openings OP1, openings OP2 and openings OP3 is selectively etched away so as to expose the conductive material 12 in the openings OP1 and the openings OP2 and the insulating material layer IL on the bottoms of the openings OP3. Accordingly, the isolation sidewalls SP1 disposed on respective sidewalls of the openings OP1, the openings OP2 and the openings OP3 can be obtained. Subsequently, as shown in FIG. 10, the conductive material 16 is formed to overlie the spacers 108 and fill the openings OP1, the openings OP2 and the openings OP3. Then a recessing process, e.g., microlithography and etching process, is performed to remove redundant part of the conductive material 16, and meanwhile, the conductive material 16 is patterned into a plurality of connection pads 302, a dam pad 304 and an extension pad 306, which are isolated from each other. After completing the recessing process, a deposition process and a planarization process are performed to form a dielectric material 402, which fills recesses among the connection pads 302, the dam pad 304 and the extension pad 306 so as to complete the semiconductor structure according to this embodiment of the present invention. Detailed descriptions of the plug structures in this embodiment, which include the first plug 21, the second plug 22, the third plug 23 and the fourth plug 24, may be understood with reference to the foregoing and will not be repeated herein for simplification. The first insulating layer 22d of the second plug 22 and the isolation sidewalls SP1 disposed between the third conductive layer 22c and the spacers 108 are connected to form a U-shaped structure. The isolation sidewalls SP1 can facilitate amelioration of current leakage between the plug structures and other components.

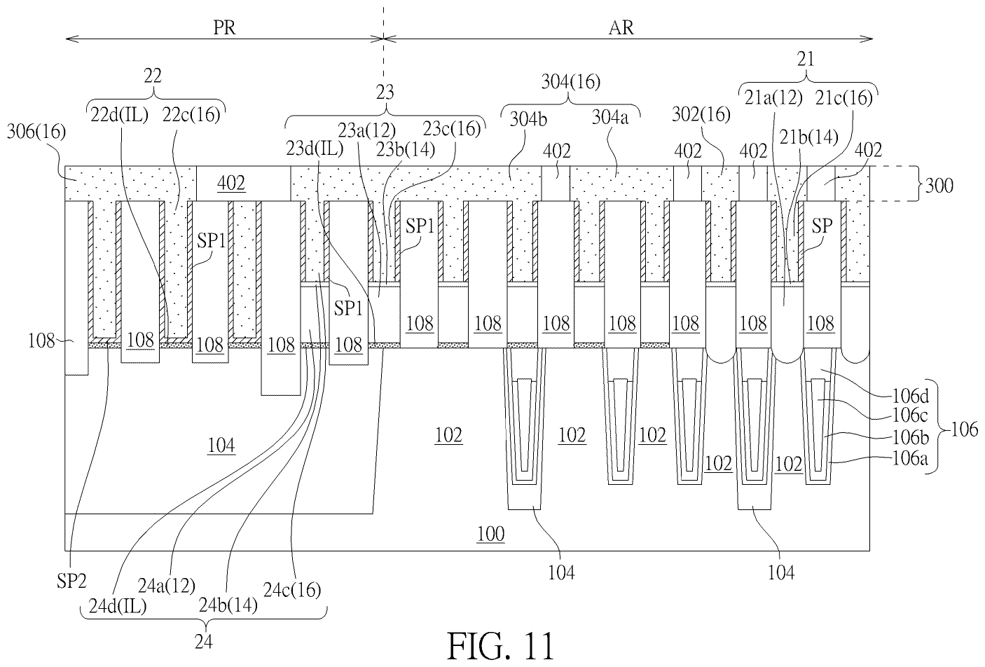

FIG. 11 is a schematic cross-sectional view illustrating a semiconductor structure according to an embodiment of the present invention. The semiconductor structure in this embodiment mainly differs from the semiconductor structure in the embodiment illustrated in FIG. 10 in that in this embodiment, the portion of the sidewall material layer SP formed on the bottoms of the openings OP3 are not removed, and instead, remained to serve as isolation pad layers SP2. Therefore, compared to the configuration of the semiconductor structure in the embodiment illustrated in FIG. 7 or FIG. 10, where the first insulating layer 22d and the third conductive layer 22c of the second plug 22 are in direct contact with each other, the first insulating layer 22d and the third conductive layer 22c are isolated from and not in contact with each other by the isolation pad layer SP2. The isolation sidewall SP1, the isolation pad layer SP2 and the first insulating layer 22d are connected to form a U-shaped structure. A thickness of a horizontal portion of the U-shaped structure, i.e., a total thickness of the first insulating layer 22d and the isolation pad layer SP2, is greater than a thickness of the second insulating layer 23d of the third plug 23 and the third insulating layer 24d of the fourth plug 24.

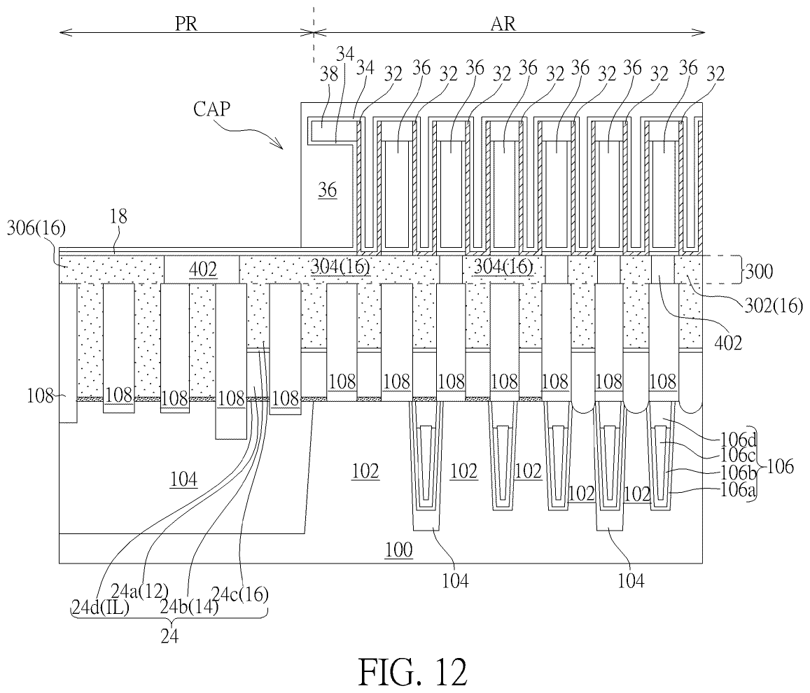

In some embodiments, a semiconductor structure according to the present invention may further include stacked capacitors. For example, refer to FIG. 12, which is a schematic cross-sectional view illustrating a semiconductor structure according to another embodiment of the present invention. The semiconductor structure includes a substrate 100, plug structures and spacers 108 alternately arranged on the substrate 100, a connecting layer 300 disposed on the plug structures and the spacers 108, and a capacitor structure CAP disposed on the connecting layer 300. The capacitor structure CAP includes a plurality of bottom electrodes 32 vertically erected on the connection layer 300, capacitive dielectric layers 34 overlying the surfaces of the bottom electrodes 32, and top electrodes 36 disposed on the capacitive dielectric layers 34 and capacitively coupled with the bottom electrodes 32 through the capacitive dielectric layers 34. The bottom electrodes 32 and the top electrodes 36 may include respective conductive materials, such as metal materials. Suitable metal materials may include, for example, but not limited to, metal such as tungsten (W), copper (Cu), aluminum (Al), titanium (Ti), tantalum (Ta), a compound, an alloy and/or a composite layer of the above-mentioned metals. In some embodiments, the top electrodes 36 may include a semiconductor material, e.g., polycrystalline silicon. The capacitive dielectric layers 34 may include a dielectric material, for example, but not limited to, silicon oxide (SiO₂), silicon nitride (SiN), silicon oxynitride (SiON), silicon nitride (SiCN), nitrogen-doped silicon carbide (NDC) or a combination of the above materials. In some embodiments, the capacitive dielectric layers 34 may include a high-k metal oxide dielectric material such as Hafnium oxide (HfO), hafnium oxide silicate (HfSiO), hafnium oxynitride silicate (HfSiON), aluminum oxide (AlO), lanthanum oxide (LaO), lanthanum aluminate (LaAlO), tantalum oxide (TaO), zirconium oxide (ZrO), zirconium oxide silicate (ZrSiO), or hafnium zirconate (HfZrO), etc., but it is not limited thereto. The capacitor structure CAP further includes at least one support layer 38 horizontally extending between the bottom electrodes 32 of the capacitor structure CAP and being in direct contact with and supporting each of the bottom electrodes 32. In some embodiments, an etch stop layer 18 may be disposed between the capacitor structure CAP and the connecting layer 300, wherein bottoms of some of the bottom electrodes 32 penetrate through the etch stop layer 18 and are in direct contact with the connection pads 302 of the connecting layer 300, respectively. In some embodiments, as shown in FIG. 8, some of the bottom electrodes 32 are disposed on the dam pad 304, and bottoms thereof penetrate through the etch stop layer 18 of the dam pad 304 and are in direct contact with the dam pad 304, thereby helping to strengthen the support of the peripheral part of the capacitor structure CAP and reduce the defects caused by deformation or collapse. The support layer 38 and the etch stop layer 18 may include respective dielectric materials, for example, but not limited to, silicon oxide (SiO₂), silicon nitride (SiN), silicon oxynitride (SiON), silicon nitride (SiCN), nitrogen-doped silicon carbide (NDC) or a combination of the above materials.

To sum up, the semiconductor structure provided according to the present invention includes plug structures alternately arranged with spacers on the substrate in the cell region and the peripheral region, and the plug structures may include the same conductive material, i.e., the conductive material 16, so that the technical effect of adjusting the stress between the cell region and the peripheral region can be achieved, and structural defects caused by stress variation due to significant differences in pattern density and material composition between the cell region and the peripheral region can be reduced. In some embodiments, the semiconductor structure also includes connection pads, a dam pad and an extension pad for electrically connecting to the components above it, e.g., the capacitor structure CAP. The pads are respectively arranged on corresponding plug structures and integrally formed with the conductive layers of the plug structures. By embedding the plug structures between the spacers, the extension pad and the dam pad which are structurally integral with the plug structures may be securely disposed on the substrate and prevented from peeling.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a substrate comprising a plurality of active areas and a trench isolation; and
a plurality of plug structures and a plurality of spacers alternately arranged on the substrate, the plurality of plug structures comprising a first plug disposed on one of the active areas and a second plug disposed on the trench isolation, wherein the first plug comprises a first conductive layer and a second conductive layer from bottom to top, the second plug comprises a first insulating layer and a third conductive layer from bottom to top, a bottom surface of the third conductive layer is lower than a bottom surface of the second conductive layer.

2. The semiconductor structure according to claim 1, wherein the first conductive layer is in direct contact with the one of the active area, and the first insulating layer is in direct contact with the trench isolation.

3. The semiconductor structure according to claim 1, wherein the substrate further comprises a cell region and a peripheral region, the active areas are disposed in the cell region, and the trench isolation is disposed in the peripheral region.

4. The semiconductor structure according to claim 1, wherein the first conductive layer comprises a semiconductor material, and the second conductive layer and the third conductive layer comprise a same metal material.

5. The semiconductor structure according to claim 4, wherein the metal material comprises tungsten, and the semiconductor material comprises polycrystalline silicon.

6. The semiconductor structure according to claim 1, further comprising a metal silicide layer between the first conductive layer and the second conductive layer, wherein the bottom surface of the third conductive layer is lower than a bottom surface of the metal silicide layer.

7. The semiconductor structure according to claim 1, further comprising an isolation sidewall between the third conductive layer of the second plug and one of the plurality of spacers, wherein the isolation sidewall and the first insulating layer form a U-shaped structure.

8. The semiconductor structure according to claim 1, wherein the plurality of plug structures further comprise a third plug, which crosses a junction between another one of the active area and the trench isolation and comprises a second insulating layer, a fourth conductive layer and a fifth conductive layer from bottom to top, wherein the first conductive layer and the fourth conductive layer comprise a same semiconductor material, and the second conductive layer, the third conductive layer and the fifth conductive layer comprise a same metal material.

9. The semiconductor structure according to claim 8, wherein each of the first insulating layer and the second insulating layer is a composite layer of silicon oxide-nitride-oxide.

10. The semiconductor structure according to claim 1, further comprising a connecting layer disposed on the plurality of plug structures and the plurality of spacers, wherein the connecting layer comprises:
a plurality of connection pads, one of which is disposed on the first plug and integrated formed with the second conductive layer; and
an extension pad disposed on the second plug and integrated formed with the third conductive layer.

11. A semiconductor structure, comprising:
a substrate comprising a cell region and a peripheral region, the cell region comprising a plurality of active areas, and the peripheral region comprising a trench isolation; and
a plurality of plug structures and a plurality of spacers alternately arranged in the cell region and the peripheral region, the plurality of plug structures comprising a first plug disposed on one of the active areas and a fourth plug disposed on the trench isolation, wherein the first plug comprises a first conductive layer and a second conductive layer from bottom to top, the fourth plug comprises a third insulating layer, a sixth conductive layer and a seventh conductive layer from bottom to top, the first conductive layer and the sixth conductive layer comprise a same semiconductor material, and the second conductive layer and the seventh conductive layer comprise a same metal material.

12. The semiconductor structure according to claim 11, wherein the first conductive layer is in direct contact with the one of the active areas, and the third insulating layer is in direct contact with the trench isolation.

13. The semiconductor structure according to claim 11, wherein the metal material comprises tungsten, and the semiconductor material comprises polycrystalline silicon.

14. The semiconductor structure according to claim 11, further comprising a metal silicide layer between the first conductive layer and the second conductive layer, and another metal silicide layer between the sixth conductive layer and the seventh conductive layer.

15. The semiconductor structure according to claim 11, further comprising an isolation sidewall between the first conductive layer of the first plug and one of the plurality of spacers and another isolation sidewall between the seventh conductive layer of the fourth plug and the one of the plurality of spacers.

16. The semiconductor structure according to claim 11, wherein the plurality of plug structures further comprise a third plug, which crosses a junction between another one of the active areas and the trench isolation and comprises a second insulating layer, a fourth conductive layer and a fifth conductive layer from bottom to top, wherein the fourth conductive layer comprises the semiconductor material, and the fifth conductive layer comprise the metal material.

17. The semiconductor structure according to claim 16, wherein the third insulating layer and the second insulating layer comprise a same material and have the same thickness.

18. The semiconductor structure according to claim 16, wherein each of the third insulating layer and the second insulating layer is a composite layer of silicon oxide-nitride-oxide.

19. The semiconductor structure according to claim 16, further comprising a connecting layer disposed on the plurality of plug structures and the plurality of spacers, wherein the connecting layer comprises:
a plurality of connection pads, one of which is disposed on the first plug and integrated formed with the second conductive layer; and
a dam pad disposed on the fourth plug and the third plug, wherein the dam pad, the fifth conductive layer and the seventh conductive layer are integrated formed.

20. The semiconductor structure according to claim 19, further comprising a capacitor structure disposed on the connecting layer, wherein some bottom electrodes of the capacitor structure are disposed on the dam pad.
